(19) United States
(12) Patent Application Publication
(10) Pub. No.: US 2007/0158665 A1
(43) Pub. Date: Jul. 12, 2007

(54) LIGHT EMITTING DIODE

(75) Inventors: Cheng-Yi Liu, Taoyuan (TW); Shih-Chieh Hsu, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NATIONAL CENTRAL UNIVERSITY, Taoyuan (TW)

(21) Appl. No.: 11/689,521

(22) Filed: Mar. 22, 2007

Related U.S. Application Data
(62) Division of application No. 11/306,418, filed on Dec. 28, 2005.

(30) Foreign Application Priority Data
Dec. 29, 2004 (TW) 94131078

(51) Int. Cl. H01L 33/00

(52) U.S. Cl. 257/88

(57) ABSTRACT

A method for fabricating a light emitting diode (LED) is provided. First, a first type doped semiconductor layer, an emitting layer and a second type doped semiconductor layer are sequentially formed on an epitaxy substrate. Then, a gold layer is formed on the second type doped semiconductor layer. Next, a silicon substrate is provided, and a wafer bonding process is performed between the silicon substrate and the gold layer. Finally, the epitaxy substrate is removed. As mentioned above, a LED with better reliability and efficiency of light-emitting is fabricated according to the method provided by the present invention. Moreover, the present invention further provides a LED.

### CROSS-REFERENCE TO RELATED APPLICATION

This application is a divisional of a prior application Ser. No. 11/306,418, filed Dec. 28, 2005, which claims the priority benefit of Taiwan application Ser. No. 93141078, filed on Dec. 29, 2004. The entirety of each of the above-mentioned patent applications is hereby incorporated by reference herein and made a part of this specification.

### BACKGROUND OF THE INVENTION

1. Field of the Invention

The present invention relates to a diode and a manufacturing method thereof, and more particularly, to a light emitting diode (LED) and a method for manufacturing the same.

2. Description of the Related Art

Recently, the light emitting diode (LED) fabricated with the compound semiconductor material containing GaN, such as GaN, AlGaN and InGaN is very popular. The group III A nitride is a material with a wide energy band gap, and the range of the wavelength of its emitting light is from the ultraviolet light to the red light, thus it covers nearly the whole range of the visible light band. In addition, comparing to the conventional light bulb, since the LED is advantageous in the characteristics of having a smaller size, a longer life time, requiring a lower driving voltage/current, durability, mercury-free (i.e. no industrial pollution) and better light-emitting efficiency (i.e. saving more electric power), the LED has been widely applied in the industry.

FIG. 1 is a schematic sectional view of a conventional LED. Referring to FIG. 1, the conventional LED 100 comprises an aluminum oxide (Al₂O₃) substrate 110, a doped semiconductor layer 122, an emitting layer 124 and a doped semiconductor layer 126. Wherein, the doped semiconductor layer 122 is disposed on the aluminum oxide substrate 110. The emitting layer 124 is disposed on a part of the doped semiconductor layer 122, and the doped semiconductor layer 126 is disposed on the emitting layer 124. It is to be noted that the type of the doped semiconductor layer 122 is different from the type of the doped semiconductor layer 126. For example, if the doped semiconductor layer 122 is a n-type doped semiconductor layer, the doped semiconductor layer 126 should be an p-type doped semiconductor layer.

Specifically, the contact pads 132 and 134 are usually disposed on the doped semiconductor layer 126 and on apart of the doped semiconductor layer 122, respectively. In addition, the contact pads 132 and 134 are usually made of a metal material. It is to be noted that the conventional LED 100 is electrically connected to a circuit board or other carrier (not shown) by the wire bonding technique or the flip chip bonding technique, and the contact pads 132 and 134 are used as the contact points for electrical connection.

In the conventional LED 100 mentioned above, since the heat dissipation of the aluminum oxide substrate 110 is rather poor. So, it has been recognized to be the main limitation for the application of high power-input LED. After a long period of high power-input, its internal temperature in active layer is gradually increased, which gradually degrades the light-emitting efficiency of the emitting layer 124. In addition, since a crowding effect is occurred on the periphery of the contact pads 132 and 134 when the components are driven, if the local current is too high, the contact pads 132 and 134 or the neighboring doped semiconductor layer 122 and 126 may be damaged, which fails the normal function of the conventional LED 100.

In addition, a second conventional LED is described in greater detail with referring to FIG. 2 hereinafter.

FIG. 2 is a schematic sectional view of another conventional LED. Referring to FIG. 2, the conventional LED 200 comprises a conductive substrate 210, a doped semiconductor layer 222, an emitting layer 224 and a doped semiconductor layer 226. Wherein, the doped semiconductor layer 222 is disposed on the conductive substrate 210. The emitting layer 224 is disposed between the doped semiconductor layer 222 and the doped semiconductor layer 226.

Similarly, a contact pad 232 is usually disposed on the doped semiconductor layer 226, and the purpose of the contact pad 232 is the same as the contact pad 132 shown in FIG. 1. However, the conductive substrate 210 has a good electrical conductive characteristic, thus the conductive substrate 210 is electrically connected to a circuit board when this conventional LED 200 is disposed on the circuit board or other carrier; and the conventional LED 200 is electrically connected to the circuit board through the conductive wires (not shown) disposed on the contact pad 232.

As mentioned above, the method for fabricating the conventional LED 200 comprises the following steps. First, the doped semiconductor layer 226, the emitting layer 224, and the doped semiconductor layer 222 are sequentially formed on the aluminum oxide substrate (not shown). Then, a wafer bonding process is applied to bond the doped semiconductor layer 222 to the conductive substrate 210. Next, a laser lift-off process is applied to remove the aluminum oxide substrate. Finally, the pad 232 is formed, and the fabrication of the conventional LED 200 is totally completed.

In the conventional technique, the doped semiconductor layer 222 is bonded to the conductive substrate 210 by using a Pd—In system. However, since a high temperature near 1000° C. is generated by the laser lift-off process and the Pd—In intermetallic compound cannot sustain such high temperature, the bonding strength between the doped semiconductor 222 and the conductive substrate 210 is degraded.

### SUMMARY OF THE INVENTION

Therefore, it is an object of the present invention to provide a method for fabricating an LED having a better interface bonding strength.

In addition, it is another object of the present invention to provide an LED having a better interface bonding reliability.

In order to achieve the objects mentioned above and others, the present invention provides a method for fabricating an LED, and the method comprises the following steps. First, a first type doped semiconductor layer, an emitting layer and a second type doped semiconductor layer are sequentially formed on an epitaxy substrate. Then, a gold layer is formed on the second type doped semiconductor layer. Next, a silicon substrate is provided, and a wafer bonding process is performed between the silicon substrate and the gold layer. Finally, the epitaxy substrate is removed.

In accordance with a preferred embodiment of the present invention, a pressure applied during the wafer bonding process mentioned above is between 1 Nt/cm² and 100 Nt/cm².

In accordance with the preferred embodiment of the present invention, the temperature applied during the wafer bonding process mentioned above is between 380° C. and 500° C.

In accordance with the preferred embodiment of the present invention, the method for removing the epitaxy substrate mentioned above comprises applying a laser lift-off process. In addition, the laser lift-off process may apply an Excimer Laser or an Nd-YAG Laser.

In accordance with the preferred embodiment of the present invention, before performing the wafer bonding process, the method further comprises performing a cleaning process on the silicon substrate.

In accordance with the preferred embodiment of the present invention, before forming the first type doped semiconductor layer, the method further comprises forming a buffer layer on the epitaxy substrate.

In accordance with the preferred embodiment of the present invention, the step of removing the epitaxy substrate further comprises simultaneously removing the buffer layer.

In accordance with the preferred embodiment of the present invention, before forming the gold layer, the method further comprises forming an ohmic contact layer on the second type doped semiconductor layer. In addition, after forming the ohmic contact layer, the method further comprises forming a reflecting layer on the ohmic contact layer.

In accordance with the preferred embodiment of the present invention, after removing the epitaxy substrate, the method further comprises forming a contact pad on the first type doped semiconductor layer.

In accordance with the preferred embodiment of the present invention, after removing the epitaxy substrate, the method further comprises removing a part of the first type doped semiconductor layer and the emitting layer to expose a partial surface of the second type doped semiconductor layer. Then, a first contact pad is formed on the first type doped semiconductor layer, and a second contact pad is formed on a part of the second type doped semiconductor layer that is not covered by the emitting layer.

In order to achieve the objects mentioned above and others, a LED is provided by the present invention. The LED comprises a silicon substrate, a gold layer and a semiconductor layer. Wherein, the gold layer is disposed on the silicon substrate, and the semiconductor layer is disposed on the gold layer. In addition, the semiconductor layer comprises a first type doped semiconductor layer, an emitting layer and a second type doped semiconductor layer. The first type doped semiconductor layer is disposed on the gold layer, and the emitting layer is disposed between the first type doped semiconductor layer and the second type doped semiconductor layer.

In order to achieve the objects mentioned above and others, the LED mentioned above further comprises an ohmic contact layer disposed between the gold layer and the semiconductor layer. In addition, the LED further comprises a reflecting layer disposed between the gold layer and the ohmic contact layer.

In order to achieve the objects mentioned above and others, the thickness of the gold layer is between 0.3 μm to 100 μm.

In accordance with the preferred embodiment of the present invention, the first type doped semiconductor layer mentioned above is an n-type doped semiconductor layer, and the second type doped semiconductor layer is a p-type doped semiconductor layer. Alternatively, the first type doped semiconductor layer mentioned above may be a p-type doped semiconductor layer, and the second type doped semiconductor layer may be an n-type doped semiconductor layer.

In accordance with the preferred embodiment of the present invention, the emitting layer mentioned above is a doped semiconductor layer composed of three or four elements.

In summary, comparing to the conventional technique, since the bonding is made of gold, and an Au—Si eutectic bonding is used as a bonding mechanism in the present invention, the LED provided by the present invention has better interface bonding reliability and light-emitting efficiency.

### BRIEF DESCRIPTION DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 is a schematic sectional view of a conventional LED.

FIG. 2 is a schematic sectional view of another conventional LED.

FIGS. 3A˜3D are the schematic sectional views illustrating a method for fabricating the LED according to a first preferred embodiment of the present invention.

FIG. 4 is an I-V curve diagram of the LED according to the first preferred embodiment of the present invention.

FIGS. 5A˜5B are the schematic sectional views illustrating a method for fabricating the LED according to a second preferred embodiment of the present invention.

### DESCRIPTION PREFERRED EMBODIMENTS

### FIRST EMBODIMENT

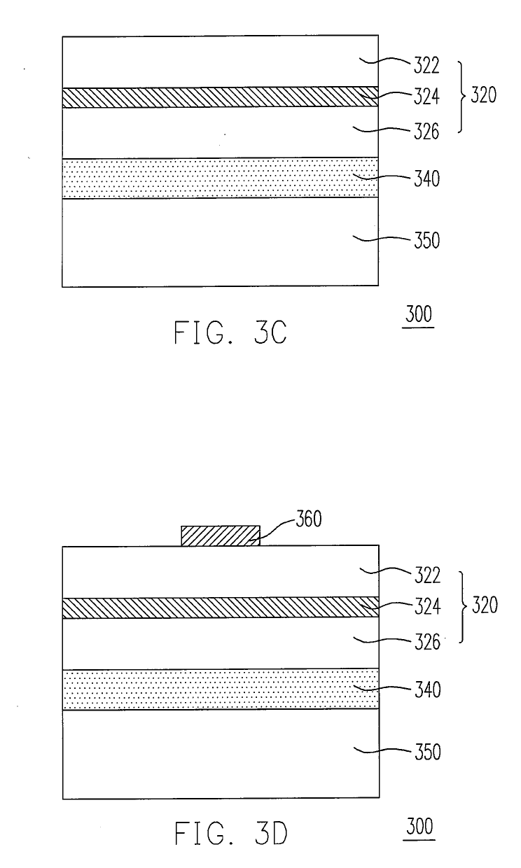

FIGS. 3A˜3D are the schematic sectional views illustrating a method for fabricating the LED according to a first preferred embodiment of the present invention. Referring to FIG. 3A, the method for fabricating the LED according of the present embodiment comprises the following steps. First, an epitaxy substrate 310 is provided; a doped semiconductor layer 322, an emitting layer 324 and a doped semiconductor layer 326 are sequentially formed on the epitaxy substrate 310. In addition, the epitaxy substrate 310 may be made of a semi-conductive or non-semi-conductive material such as Glass, GaAs, GaN, AlGaAs, GaP, SiC, InP, BN, Al₂O₃ or AIN. It is to be noted that in order to improve the electrical characteristic of the doped semiconductor layer 322, a buffer layer 330 may be formed on the epitaxy substrate 310 before the doped semiconductor layer 322 is formed.

Referring to FIG. 3B, then a gold layer 340 is formed on the doped semiconductor layer 326, and the gold layer 340 is formed by such as the e-beam evaporation process, the thermal evaporation process, the sputtering process, physical vapor deposition (PVD) process, chemical vapor deposition (CVD) or other metal filming process. Then, a silicon substrate 350 is provided; and the silicon substrate 350 may be a silicon wafer. In addition, the silicon substrate 350 may be a high doped and low resistance silicon wafer.

Afterwards, a wafer bonding process is performed on the silicon substrate 350 and the gold layer 340. Specifically, an Au—Si eutectic bonding is formed between the silicon substrate 350 and the gold layer 340, and the temperature applied during the wafer bonding process is higher than the Au—Si eutectic temperature (the eutectic temperature is 363° C.). Moreover, the thickness of the Au—Si eutectic layer increases along with the increasing of the time a high temperature is applied thereon.

For example, the pressure applied during the wafer bonding process is between 1 Nt/cm² and 100 Nt/cm², preferably 20 Nt/cm². In addition, the temperature applied during the wafer bonding process is between 380° C. and 500° C., and is preferably 400° C. However, the present embodiment does not intend to limit the pressure and temperature applied during the wafer bonding process. It is to be noted that in order to improve the interface characteristic of the silicon substrate 350, before performing the wafer bonding process, the method further comprises a cleaning process; and the cleaning process may be an RCA cleaning process or other wafer cleaning process.

Referring to FIG. 3C, after the wafer bonding process is completed, the epitaxy substrate 310 is removed, and the preliminary fabrication of the LED 300 is completed. In addition, a laser lift-off process may be used to remove the epitaxy substrate 310 in the present embodiment, and the laser lift-off process may apply an Excimer Laser. For example, the laser lift-off process may apply a KrF Excimer Laser with a wavelength of 248 nanometers. It is to be noted that if a buffer layer 330 is formed, the epitaxy substrate 310 and the buffer layer 330 should be removed at the same time.

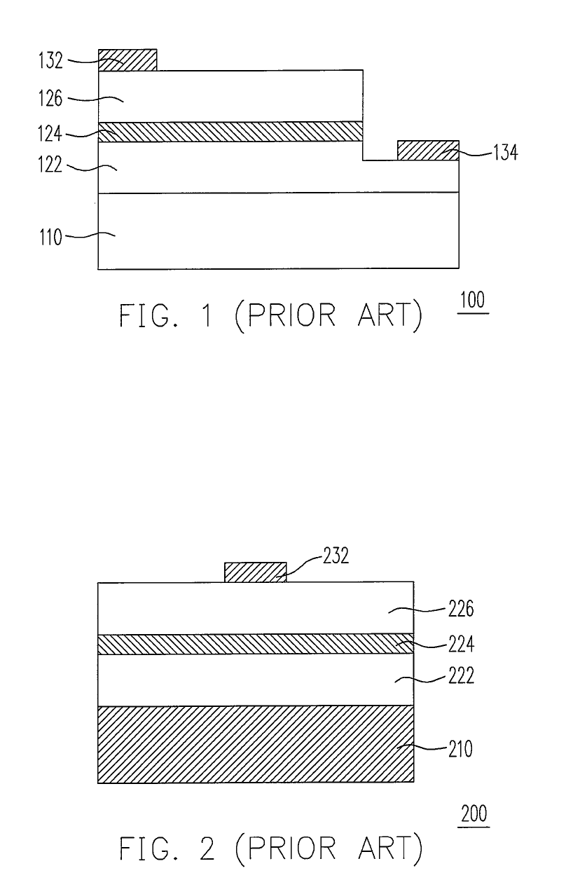

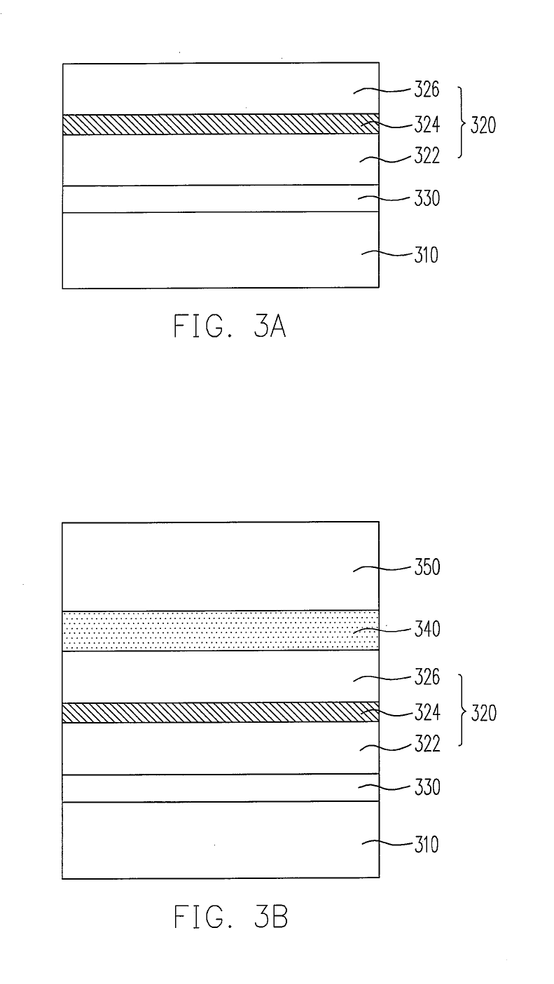

Referring to FIG. 3D, the structure formed by the manufacturing process mentioned above may be a flat LED (similar to the one shown in FIG. 1) or a vertical LED (similar to the one shown in FIG. 2). For fabricating the vertical LED, a contact pad 360 is formed on the doped semiconductor layer 322 after the epitaxy substrate 310 is removed. Moreover, the structure of the LED 300 is described in greater detail hereinafter.

Referring to FIG. 3D, the LED 300 comprises a silicon substrate 350, a gold layer 340 and a semiconductor layer 320. Wherein, the gold layer 340 is disposed between the silicon substrate 350 and the semiconductor layer 320, and the thickness of the gold layer 340 is between 0.3 μm and 100 μm. In addition, the semiconductor layer 320 comprises a doped semiconductor layer 322, a doped semiconductor layer 326 and an emitting layer 324 that is disposed between the doped semiconductor layers 322 and 326. Specifically, if the LED 300 is a vertical LED, the LED 300 further comprises a contact pad 360 that is disposed on the doped semiconductor layer 322. Moreover, the silicon substrate 350 is made of an conductive material.

Regarding to the semiconductor layer 320, if the doped semiconductor layer 322 is an n-type doped semiconductor layer, the doped semiconductor layer 326 should be a p-type doped semiconductor layer. Contrarily, if the doped semiconductor layer 322 is a p-type doped semiconductor layer, the doped semiconductor layer 326 should be an n-type doped semiconductor layer. Moreover, the material of the emitting layer 324 may contain a quantum well structure that is mainly composed of the III-V chemical family elements, such as GaN, GaAs, AIN, InGaN, and the doped semiconductor layer such as AlGaN composed of three elements, or GaInAsN and GaInPN composed of four elements. In addition, the electrical characteristics of the LED 300 are described in detail below.

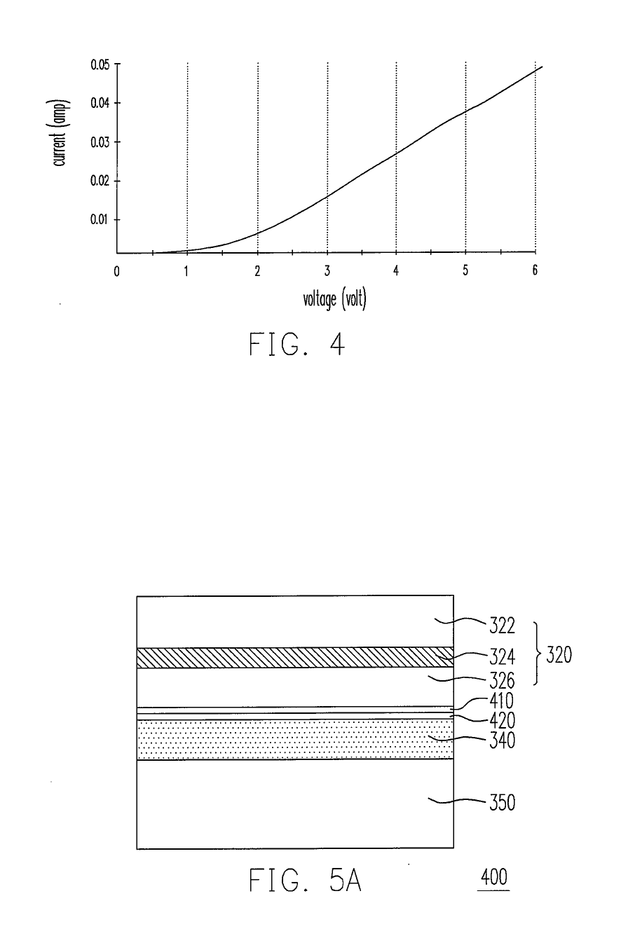

FIG. 4 is an I-V curve diagram of the LED according to the first preferred embodiment of the present invention, wherein the X-axis represents the voltage value (volt), and the Y-axis represents the current value (amp). Referring to FIG. 4, the forward voltage is about 3.4 volts when the current is 20 mA. In other words, a better electrical characteristic is provided by the Au—Si eutectic bonding between the silicon substrate 350 and the gold layer 340.

Comparing to the conventional technique where the bonding is made by the Pd—In system, a bonding is formed by the gold in the present invention, such that a certain bonding strength between the gold layer 340 and the silicon substrate 350 is sustained after a high temperature laser lift-off process is performed. In other words, the LED 300 formed by the present invention has higher bonding strength and thermal stability. Furthermore, the LED 300 formed by the present invention has better electrical characteristics.

### SECOND EMBODIMENT

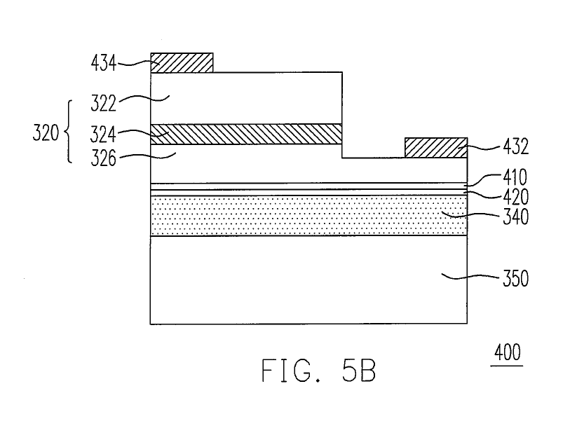

FIGS. 5A˜5B are the schematic sectional views illustrating a method for fabricating the LED according to a second preferred embodiment of the present invention. Referring to FIG. 5A, the second embodiment is similar to the first embodiment; and the difference is: in the method for fabricating the LED 400 of the second embodiment, in order to improve the electrical characteristic of the interface between the gold layer 340 and the doped semiconductor layer 326, after the doped semiconductor layer 326 is formed, an ohmic contact layer 410 is formed on the doped semiconductor layer 326, such that the electrical characteristic of the interface between the gold layer 340 and the doped semiconductor layer 326 is improved. For example, if the doped semiconductor layer 326 is the p-type doped semiconductor layer, the ohmic contact layer 410 may be made of Ni/Au layer. In addition, in order to improve the light-emitting efficiency, after forming the ohmic contact layer 410, a reflecting layer 420 is formed on the ohmic contact layer 410; and the reflecting layer 420 is made of Al.

Referring to FIG. 5B, the structure formed by the manufacturing process mentioned above may be a flat LED (similar to the one shown in FIG. 1) or a vertical LED (similar to the one shown in FIG. 2). For fabricating the flat LED, after the epitaxy substrate 310 is removed, a part of the doped semiconductor layer 322 and the emitting layer 324 are removed, so as to expose a partial surface of the doped semiconductor layer 326. Then, a contact pad 434 is formed on the doped semiconductor layer 322, and a contact pad 432 is formed on the doped semiconductor layer 326 that is not covered by the emitting layer 324, such that the fabrication of the LED 400 is completed.

It is to be noted that the structure shown in FIG. 5B may be fabricated as a flat LED, and the structure shown in FIG. 5A may be fabricated as a vertical LED.

In summary, the LED and the method for fabricating the LED provided by the present invention at least have the following advantages:

1. Comparing to the conventional technique, a bonding is formed of Au—Si eutectic system in the present invention, thus the LED of the present invention has better bonding strength and higher thermal stability. Moreover, the LED of the present invention also has better electrical characteristics.

2. The method for fabricating the LED according to the present invention is compatible with the current fabricating process, thus it is not required to add additional fabricating equipment in the present invention.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A light emitting diode (LED), comprising:
a silicon substrate;
a gold layer disposed on the silicon substrate; and
a semiconductor layer disposed on the gold layer and comprising a first type doped semiconductor layer, an emitting layer, and a second typed semiconductor layer, wherein the first type doped semiconductor layer is disposed on the gold layer, and the emitting layer is disposed between the first type doped semiconductor layer and the second type doped semiconductor layer.

2. The LED of claim 1, further comprising an ohmic contact layer disposed between the gold layer and the semiconductor layer.

3. The LED of claim 2, further comprising a reflecting layer disposed between the gold layer and the ohmic contact layer.

4. The LED of claim 1, wherein the thickness of the gold layer is between 0.3 μm and 100 μm.

5. The LED of claim 1, wherein the first type doped semiconductor layer is an n-type doped semiconductor layer, and the second type doped semiconductor layer is a p-type doped semiconductor layer.

6. The LED of claim 1, wherein the first type doped semiconductor layer is a p-type doped semiconductor layer, and the second type doped semiconductor layer is an n-type doped semiconductor layer.

7. The LED of claim 1, wherein the emitting layer is a doped semiconductor layer composed of three or four chemical elements.
